(19) United States
(12) Patent Application Publication
(10) Pub. No.: US 2007/0007580 A1
(43) Pub. Date: Jan. 11, 2007

(54) Non-Volatile Memory Devices Having Floating Gates that Define a Void and Methods of Forming Such Devices

(76) Inventors: Jai-Hyuk Song, Seoul (KR); Jeong-Hyuk Choi, Gyeonggi-do (KR); Ki-Nam Kim, Seoul (KR); Jong-Kwang Lim, Gyeonggi-do (KR)

Correspondence Address: MYERS BIGEL SIBLEY & SAJOVEC, PO BOX 37428, RALEIGH, NC, 27627, US

(21) Appl. No.: 11/428,690

(22) Filed: Jul. 5, 2006

(30) Foreign Application Priority Data
Jul. 8, 2005 (KR) 2005-61836

(51) Int. Cl. H01L 29/788

(52) U.S. Cl. 257/315

(57) ABSTRACT

Non-volatile memory devices include a floating gate having a lower portion and a pair of walls extending upward from opposite edges of the lower portion to define a void. An overlap area between adjacent floating gates is decreased by a side area of the void defined by the lower portion and the walls, so that a parasitic electrostatic capacitance can be reduced.

### CLAIM OF PRIORITY

This application claims priority under 35 U.S.C. § 119 from Korean Patent Application No. 2005-61836, filed on Jul. 8, 2005, the disclosure of which is hereby incorporated by reference herein as if set forth in its entirety.

### FIELD OF THE INVENTION

The present invention relates to semiconductor devices and to methods of forming the same and, more particularly, to non-volatile memory devices and methods of forming such devices.

### BACKGROUND OF THE INVENTION

Non-volatile memory devices are a class of semiconductor memory devices that retain stored data even when the power supply to the device is cut off. Flash memory devices are one type of non-volatile memory device. A conventional flash memory device includes a plurality of flash memory cells. Each flash memory cell includes a floating gate. Electrons are stored in, or emitted from, the floating gate, so that the flash memory cell can store data having a value of either logic “0” or logic “1.” The flash memory device will retain the stored data even after the power to the cell has been cut-off or otherwise interrupted. Data can be repeatedly programmed into, and erased from, flash memory cells.

In order to achieve a high degree of integration, a flash memory device may have a stack type gate stricture, in which the control gate of each flash memory cell is stacked on top of the cell's floating gate. A conventional flash memory device having such a stack type gate structure will now be described with reference to FIGS. 1A-1C. FIG. 1A is a plan view of the conventional flash memory device, and FIGS. 1B and 1C are cross-sectional diagrams taken along lines I-I′ and II-II′, respectively, of FIG. 1A.

Referring to FIGS. 1A, 1B and 1C, device isolation layers 2 are disposed in a substrate 1 in order to define an active region therebetween. Control gate electrodes 6 are formed side by side across the active region. A floating gate 4 is disposed between each control gate electrode 6 and the active region, and a tunnel oxide layer 3 is interposed between each floating gate 4 and the active region. An oxide-nitride-oxide (ONO) layer 5 is interposed between each floating gate 4 and its corresponding control gate electrode 6. Impurity doped regions 7 are disposed in the active region at both sides of each control gate electrode 6. The floating gate 4 has a pair of first side surfaces that are adjacent to the device isolation layers 2, and a pair of second side surfaces that are adjacent to the impurity doped regions 7.

As shown in FIGS. 1A-1C, in the conventional flash memory device, the control gate electrode 6 covers a top surface and the first side surfaces of the floating gate 4. As a result, a relatively high electrostatic capacitance may exist between the control gate electrode 6 and the floating gate 4. Increases in the electrostatic capacitance may result in an increase in the coupling ratio of the flash memory cell. Such an increase in the coupling ratio may reduce an operating voltage of the flash memory device.

### SUMMARY OF THE INVENTION

Pursuant to embodiments of the present invention, non-volatile memory devices (and methods of forming such devices) are provided that may reduce and/or minimize the parasitic electrostatic capacitance between adjacent non-volatile memory cells. Embodiments of the present invention also provide non-volatile memory devices (and methods of forming such devices) that may reduce and/or minimize etching damage to the active region at both sides of a floating gate as well as reducing and/or minimizing a parasitic electrostatic capacitance.

Pursuant to certain embodiments of the present invention, non-volatile memory devices are provided that include an active region in a semiconductor substrate. A floating gate is provided on the active region. The floating gate has a lower portion and a pair of facing walls extending upward from opposite edges of the lower portion that define a void above the lower portion. A tunnel insulating layer is interposed between the active region and the lower portion of the floating gate. A control gate electrode is on the floating gate aid covering outer surfaces of the pair of facing walls. One or more insulating materials are interposed between the control gate electrode and the floating gate in order to fill the void. Finally, the device includes first and second impurity-doped regions in the active region at opposite sides of the control gate electrode.

In some embodiments, the one or more insulating materials may comprise a capping pattern that at least partially fills the void and a blocking insulation pattern that is interposed between the control gate electrode and the floating gate. A top surface of the capping pattern may be at least at about the same height above the substrate as a top surface of at least one of the walls. In other embodiments, a top surface of the capping pattern may be lower than a top surface of at least one of the walls so that the capping pattern does not completely fill the void, and the blocking insulation pattern is deposited in at least a portion of the remainder of the void. A side surface of the capping pattern that is adjacent the first impurity-doped region may be aligned with a side surface of the floating gate that is adjacent the first impurity-doped region.

In other embodiments, the one or more insulating materials may consist of a blocking insulating pattern that fills the void and that is interposed between the control gate electrode and the floating gate.

In some embodiments, a thickness of the lower portion is greater than a width of at least one of the walls. Also, a width of at least one of the walls may be greater than a width of the void. The walls may comprise doped polysilicon, and the walls may be configured so as to be partially depleted when an operating voltage is applied to the control gate electrode. Moreover, each of the facing walls of the floating gate may be normal to the lower portion of the floating gate. A height of a lower surface of the control gate above the substrate may be lower than a height of a top surface of the lower portion of the floating gate above the substrate. Also, the lower portion of the floating gate may be flat and may extend parallel to a major axis of the substrate.

Pursuant to further embodiments of the present invention, non-volatile memory devices are provided that include an active region in a semiconductor substrate. A floating gate is on the active region. The floating gate includes a lower portion and a pair of facing walls that extend upward from opposite edges of the lower portion to define a void above the lower portion. A tunnel insulating layer is interposed between the active region and the lower portion of the floating gate. One or more insulating materials are provided on the lower portion of the floating gate that partially fill the void. A control gate electrode is provided on the one or more insulating materials, the control gate electrode covering outer surfaces of the pair of facing walls and including a gap-fill portion that has a width that is less than a width of each of pair of facing walls, the gap-fill portion extending into the void. First and second impurity-doped regions are included in the active region at opposite sides of the control gate electrode.

The one or more insulating materials may comprise a capping pattern that at least partially fills the void and a blocking insulation pattern that is interposed between the control gate electrode and the capping pattern. A side surface of the capping pattern that is adjacent the first impurity-doped region may be aligned with a side surface of the floating gate that is adjacent the first impurity-doped region. The thickness of the lower portion may be greater than a width of at least one of the walls.

The value obtained by subtracting a thickness of the blocking insulating pattern from a depth of the void is greater than a thickness of the lower portion. Moreover, a side surface of the floating gate that is adjacent the first impurity-doped region may be aligned with side surface of the control gate electrode that is adjacent the first impurity-doped region.

Pursuant to still further embodiments of the present invention, methods of forming non-volatile memory devices are provided in which device isolation layers are formed in a substrate to define an active region. A tunnel insulating layer is formed on the active region, and a pre-floating gate is formed on the tunnel insulating layer. The pre-floating gate has a flat lower portion that covers the active region and a pair of facing walls that extend upward from opposite edges of the flat lower portion. A void defined by the flat lower portion and the pair of facing walls is then filled with an insulating material. A blocking insulating layer is formed on at least the flat lower portion and at least part of the outer surfaces of the walls of the pre-floating gate. A control gate conductive layer is formed on the blocking insulating layer. Finally, a floating gate, an insulating material pattern, a blocking insulating pattern, and a control gate electrode are formed by patterning the control gate conductive layer, the blocking insulating layer, the insulating material, and the pre-floating gate.

In some embodiments of these methods, the insulating material that is used to fill all or part of the void is a capping layer. In such embodiments, a top surface of the capping layer may be at about the same level as a top surface of at least one of the walls. In other embodiments, a top surface of the capping layer may be lower than a top surface of at least one of the walls, and the blocking insulating layer is formed to fill the remainder of the void above the capping layer. In still other embodiments, the blocking insulating layer may completely fill the void.

In some embodiments of these methods, the pre-floating gate may be etched to make a thickness of the flat lower portion greater than a width of the walls. The floating gate may be formed of doped polysilicon, and the walls of the floating gate may have a width that allow the walls to be partially depleted when an operating voltage is applied to the control gate electrode. The a width of at least one of the walls may exceed a width of the void.

Pursuant to still further embodiments of the present invention, methods of forming a non-volatile memory device are provided in which device isolation layers are formed in a substrate to define an active region. A tunnel insulating layer is formed on the active region. A pre-floating gate is formed on the tunnel insulating layer, the pre-floating gate including a lower portion covering the active region and a pair of walls extending upward from opposite edges of the lower portion that define a void above the lower portion. A blocking insulating layer is conformally formed on the substrate so as to partially fill the void. A control gate conductive layer is formed on the blocking insulating layer, the control gate conductive layer covering outer surfaces of the walls and including a gap-fill portion that fills the remainder of the void. Finally, a floating gate, blocking insulating pattern, and a control gate electrode are formed by patterning the control gate conductive layer, the blocking insulating layer, and the pre-floating gate. In the devices formed by these methods, the width of at least one of the walls of the pre-floating gate is greater than a width of a gap-fill portion of the control gate conductive layer.

### BRIEF DESCRIPTION OF THE DRAWINGS

The accompanying drawings, which are included to provide a further understanding of the invention and are incorporated in and constitute a part of this application, illustrate certain embodiment(s) of the invention. In the drawings:

FIG. 1A is a plan view of a conventional flash memory device;

FIGS. 1B and 1C are cross-sectional diagrams taken along lines I-I′ and II-II′ of FIG. 1A, respectively;

FIG. 2 is a plan view of a non-volatile memory device according to some embodiments of the present invention;

FIGS. 3A and 3B are cross-sectional diagrams taken along lines III-III′ and IV-IV′ of FIG. 2, respectively;

FIGS. 4A and 4B are cross-sectional diagrams taken along lines III-III′ and IV-IV′ of FIG. 2, respectively, illustrating non-volatile memory devices according to further embodiments of the present invention;

FIGS. 5A and 5B are cross-sectional diagrams taken along lines III-III′ and IV-IV′ of FIG. 2, respectively, illustrating non-volatile memory devices according to still further embodiments of the present invention;

FIGS. 6A through 10A and 6B through 10B are cross-sectional diagrams taken along lines III-III′ and IV-IV′ of FIG. 2, respectively, illustrating methods of forming non-volatile memory devices according to some embodiments of the present invention;

FIGS. 11A and 11B are cross-sectional diagrams taken along lines III-III′ and IV-IV′ of FIG. 2, respectively, illustrating methods of forming the non-volatile memory device illustrated in FIGS. 5A and 5B;

FIG. 12 is a plan view of a non-volatile memory device according to still further embodiments of the present invention;

FIGS. 13A and 13B are cross-sectional diagrams taken along lines V-V′ and VI-VI′ of FIG. 12, respectively;

FIGS. 14A and 14B are cross-sectional diagrams taken along lines V-V′ and VI-VI′ of FIG. 12, respectively, illustrating non-volatile memory devices according to still further embodiments of the present invention;

FIGS. 15A through 17A and 15B through 17B are cross-sectional diagrams taken along lines V-V′ and VI-VI′ of FIG. 12, respectively, illustrating methods of forming non-volatile memory devices according to further embodiments of the present invention; and

FIGS. 18A and 18B are cross-sectional diagrams taken along lines V-V′ and VI-VI′ of FIG. 12, respectively, illustrating methods of forming the non-volatile memory device illustrated in FIGS. 14A and 14B.

### DETAILED DESCRIPTION OF THE INVENTION

Embodiments of the present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Other words used to describe the relationship between elements should be interpreted in a like fashion (i.e., “between” versus “directly between”, “adjacent” versus “directly adjacent”, etc.).

Relative terms such as “below” or “above” or “upper” or “lower” or “horizontal” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this disclosure and the relevant art and will not be interpreted in an idealized or overly formal sense unless expressly so defined herein.

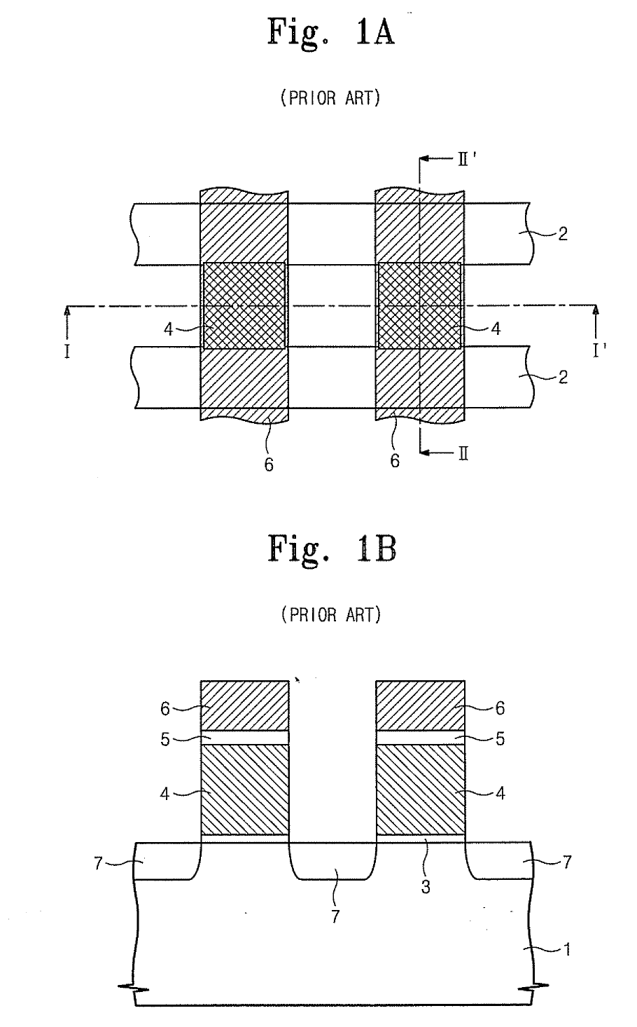

In order to increase the level of integration of a flash memory device such as the prior art device depicted in FIGS. 1A-1C, the height of the floating gate 4 (and hence the area of each first side surface) may be increased so that the area of overlap between the floating gate 4 and the control gate electrode 6 may be increased within a limited area. However, such an increase in the height of the floating gate 4 may also cause an increase in the area of each of the second side surfaces of the floating gate 4, which causes an increase in the an overlap area between adjacent floating gates 4. This increase in the area of overlap between adjacent floating gates 4 may increase the parasitic capacitance between adjacent cells, which can cause the flash memory cells to malfunction. When a program operation or an erase operation is performed on a selected floating gate 4 that exhibits such increased parasitic capacitance, soft programming or soft erasing may occur on the floating gate 4 adjacent to the selected floating gate 4. Pursuant to embodiments of the present invention, highly integrated flash memory devices may be provided that have reduced and/or minimized parasitic capacitance between adjacent floating gates.

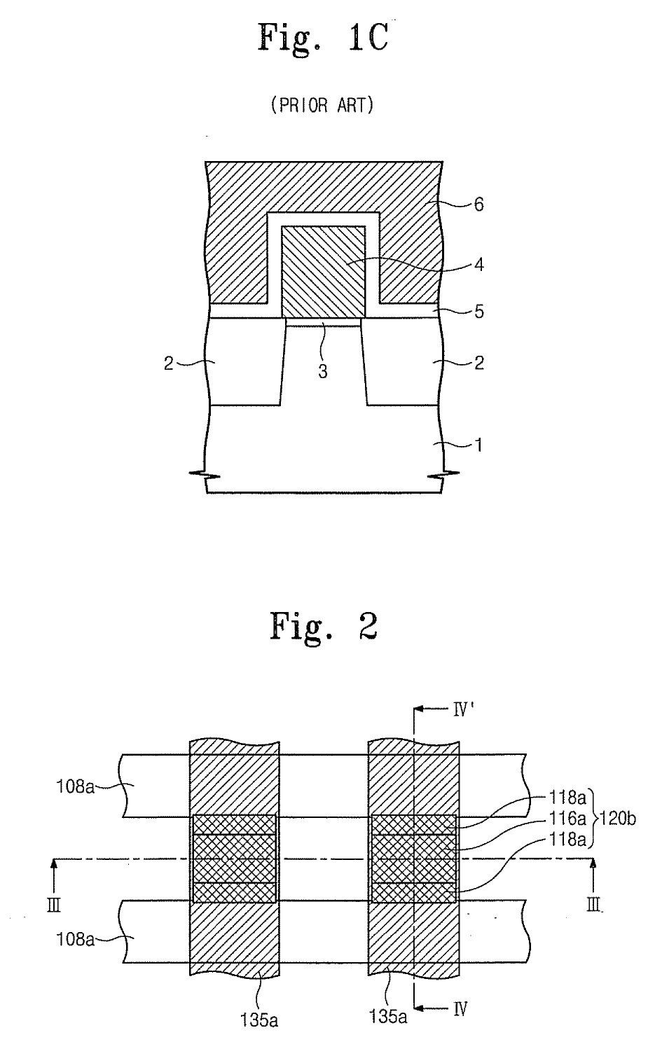

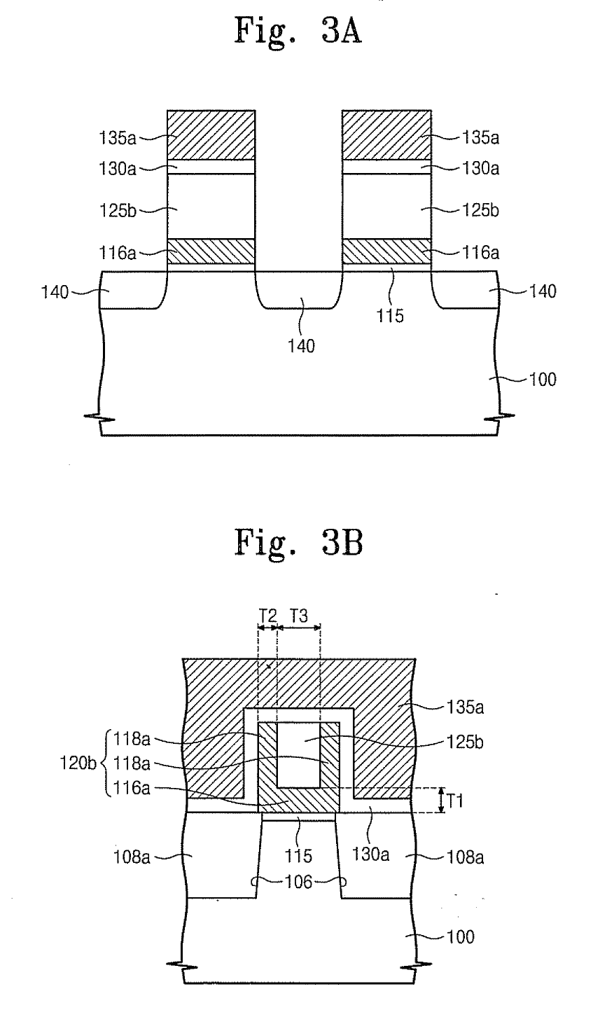

FIG. 2 is a plan view of a non-volatile memory device according to some embodiments of the present invention. FIGS. 3A and 3B are cross-sectional diagrams taken along lines III-III′ and IV-IV′ of FIG. 2, respectively.

Referring to FIGS. 2, 3A and 3B, device isolation layers 108a are disposed in a substrate 100 to define an active region. The device isolation layers 108a may be formed by filling trenches 106 formed in predetermined regions of the substrate 100. The substrate 100 may be a conventional semiconductor substrate, a silicon-on-insulator substrate, or some other semiconductor layer suitable for forming an active region therein, all of which may be referred to herein as a “substrate.” A floating gate 120b is disposed on the active region. A tunnel insulating layer 115 is interposed between the floating gate 120b and the active region. Impurity-doped regions 140 are disposed at both sides of the floating gate 120b in the active region. The impurity-doped regions 140 correspond to source/drain regions of a non-volatile memory cell.

As shown best in FIG. 3B, the floating gate 120b includes a flat lower portion 116a, and a pair of facing walls 118a that extend upward from edges of the flat lower portion 116a that are adjacent to the device isolation layers 108a. As shown in FIGS. 3A and 3B, the tunnel insulating layer 115 is interposed between the flat lower portion 116a and the active region. The flat lower portion 116a and the wall portions 118a may be formed as a single layer.

The flat lower portion 116a may extend laterally to overlap the device isolation layer 108a on either or both sides of the floating gate 120b, as shown in FIG. 3B. A top surface of the device isolation layer 108a may be at approximately the same height above the substrate 100 as is the bottom surface of the flat lower portion 116a. In other embodiments, the device isolation layer 108a may have a top surface that is lower than a top surface of the active region. The device isolation layer 108a may cover a side surface of the tunnel insulating layer 115.

As shown in FIG. 3B, the flat lower portion 116a and the pair of walls 118a of the floating gate 120b define an open area or “void.” This void may be filled with an insulating material. As shown in FIGS. 3A and 313, the void is open at its top and on both of the sides that are adjacent to one of the impurity-doped regions 140. In the embodiment of FIGS. 3A and 3B, a capping pattern 125b that may be formed of an insulative material is disposed within the void. A top surface of the capping pattern 125b may be at about the same level as, or higher than, the top surfaces of the walls 118a. The capping pattern 125b may fill the void. The capping pattern 125b may be formed of an insulating material that has etching selectivity with respect to the device isolation layer 108a. For example, the device isolation layer 108a may be formed of silicon oxide, and the capping pattern 125b may be formed of silicon nitride or silicon nitride-oxide.

The capping pattern 125b may contact a top surface of the flat lower portion 116a and inner surfaces of the walls 118a. As shown best in FIG. 3A, side surfaces of the capping pattern 125b which are adjacent to the impurity-doped regions 140 are aligned with the side surfaces of the floating gate 120b which are adjacent to the impurity-doped regions 140.

A control gate electrode 135a is formed across the active region on the floating gate 120b. A blocking insulating pattern 130a is interposed between the control gate electrode 135a and the floating gate 120b. The blocking insulating pattern 130a is also interposed between the capping pattern 125b and the control gate electrode 135a. As shown in FIG. 3B, the control gate electrode 135a may cover the top surfaces of the walls 118a of the floating gate 120b, a top surface of the capping pattern 125b, and the outer side surfaces of the walls 118a that are adjacent to the device isolation layers 108a. As shown in FIG. 3A, the side surfaces of the floating gate 120b, the capping pattern 125b, the blocking insulating pattern 130a and the control gate electrode 135a, which are adjacent to the impurity-doped regions 140, are aligned with each other. Each impurity-doped region 140 may be aligned with the floating gate 120b and the control gate electrode 135a.

As shown in FIG. 3B, the thickness (T1) of the flat lower portion 116a is greater than a width (T2) of each of the walls 118a. Herein, the “width” of a wall 118a (i.e., the distance T2) refers to the distance between an outer side surface of the wall 118a that is adjacent to the device isolation layer 108a and an opposite inner side surface thereto. The width (T2) of the wall 118a may be smaller than a width (T3) of the void. Alternatively, the width (T2) of the wall 118a may be greater than the width (T3) of the void. Herein, the “width” of the void refers to the distance between the walls 118a. The width (T3) of the void may be identical to the width of the capping pattern 125b (as the capping pattern 125b may fill the void).

The floating gate 120b may be formed of doped polysilicon. The width (T2) of each wall 118a may be partially depleted when an operating voltage is applied to the control gate electrode 135. In particular, when an operating voltage is applied to the control gate electrode 135a, a depletion layer may be formed at each wall 118a. For example, when the floating gate 120b is formed of n-doped polysilicon and a negative voltage (e.g., an erase voltage) is applied to the control gate electrode 135a, a depletion layer may be formed at each wall 118a. Here, the wall 118a having the partially-depleted width may reduce and/or minimize a decrease in electrostatic capacitance between the control gate electrode 135a and the floating gate 120b which is caused by the depletion layer. Because the depletion layer functions in a manner similar to the dielectric layer of a capacitor, when the wall 118a is completely depleted, the electrostatic capacitance between the floating gate 120b and the control gate electrode 135a can be rapidly reduced.

In the above-described non-volatile memory device, the floating gate 120b includes the flat lower portion 116a and the pair of walls 118a. Accordingly, the area of each side surface of the floating gate 120b that is adjacent to one of the impurity-doped regions 140 is reduced by the side area of the void (see FIG. 3B). Thus, the overlap area between adjacent floating gates 120b may be significantly decreased, thereby reducing the parasitic electrostatic capacitance between adjacent floating gates 120b. As such, non-volatile memory devices having improved reliability may be provided.

Also, the void is filled with a capping pattern 125b, which may be an insulating material. The capping pattern 125b may help reduce etching damage to the active region at both sides of the floating gate 120b, which may otherwise result during an etching process used in forming the control gate electrode 135a, the blocking insulating pattern 130a and/or the floating gate 120b. Thus, the capping pattern 125b may help reduce leakage currents that may be generated at both sides of the floating gate 120b if etching damage to the active region occurs. In addition, as noted above, the thickness (T1) of the flat lower portion 116a may exceed the width (T2) of the walls 118a, which may also help reduce/minimize etching damage to the active region.

In some embodiments, the width (T2) of each wall 118a may be greater than the width (T3) of the void. In these embodiments, the area of the top surface of the wall 118a is larger, which may increase the area of overlap between the control gate electrode 135a and the floating gate 120b, which may increase the electrostatic capacitance between the control gate electrode 135a and the floating gate 120b.

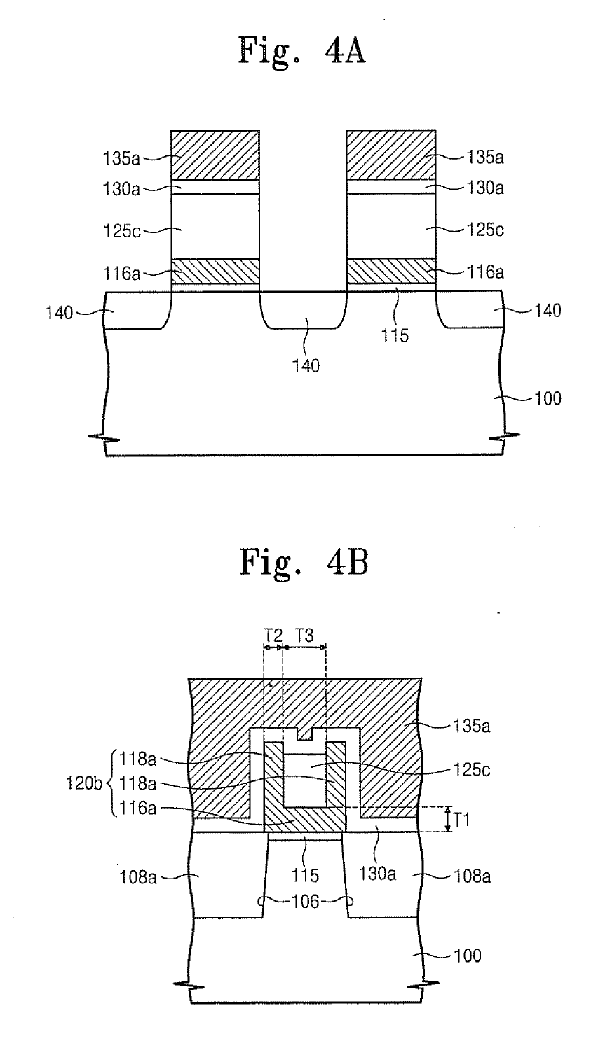

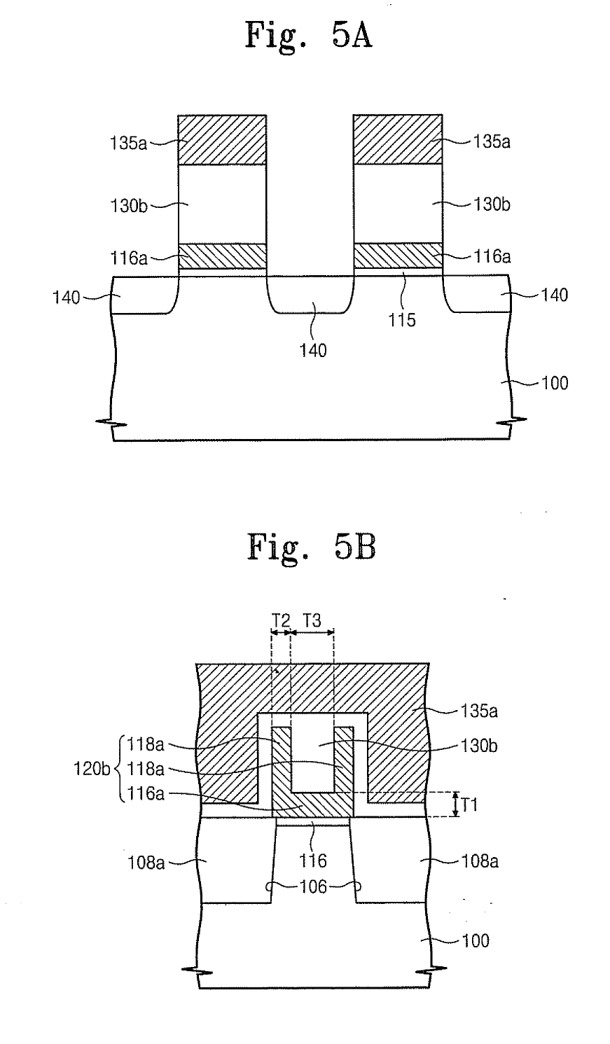

FIGS. 4A and 4B are cross-sectional diagrams taken along lines III-III′ and IV-IV′ of FIG. 2, respectively, illustrating a non-volatile memory device according to additional embodiments of the present invention. FIGS. 5A and 5B are cross-sectional diagrams taken along lines III-III′ and IV-IV′ of FIG. 2, respectively, illustrating a non-volatile memory device according to still further embodiments of the present invention. The non-volatile memory devices of FIGS. 4A-4B and 5A-5B differ from the above-described embodiments in that they use different insulating materials to fill the void defined by the flat lower portion 116a and the walls 118a of the floating gate 120b.

Referring to FIGS. 4A and 4B, a capping pattern 125c is disposed within the void defined by the flat lower portion 116a and the pair of a walls 118a of a floating gate 120b. In this embodiment, the top surface of the capping pattern 125c is lower than the top surfaces of the walls 118a such that the capping pattern 125c fills only a portion of the void. Side surfaces of the capping pattern 125c that are adjacent to the impurity-doped regions 140 are aligned with the side surfaces of the floating gate 120b that are adjacent to the impurity-doped layer 140. The remaining portion of the void above the capping pattern 125c is filled with a portion of the blocking insulating pattern 130a. A control gate electrode 135a is disposed on the blocking insulating pattern 130a.

In the embodiment of FIGS. 4A and 4B, the insulating materials that are deposited in the void include the capping pattern 125c and a portion of the blocking insulating pattern 130a. The void-filling insulating materials may reduce and/or minimize etching damage to the active region at both sides of the floating gate 120b. The non-volatile memory device illustrated in FIGS. 4A and 4B may obtain the effects described above with reference to the embodiment of FIGS. 3A and 3B.

In the embodiment of FIGS. 5A and 5B, the blocking insulating pattern 130b that is interposed between the control gate electrode 135a and the floating gate 120b extends downward to fill the void defined by the flat lower portion 116a and the pair of walls 118a of the floating gate 120b. Thus, the blocking insulating pattern 130b contacts both the walls 118a and the flat lower portion 116a that define this void. The portion of the blocking insulating pattern 130b that is deposited in the void comprises the insulating material that fills the void. The capping patterns 125b and 125c that are deposited within the void in the embodiments of FIGS. 3A, 3B, 4A and 4B are not used in the embodiment of FIGS. 5A and 5B. The portion of the blocking insulating pattern 130b that is deposited in the void may reduce and/or minimize etching damage to the active region at both sides of the floating gate 120b. The non-volatile memory device illustrated in FIGS. 5A and 5B may also obtain the effects described above with reference to the embodiment of FIGS. 3A and 3B.

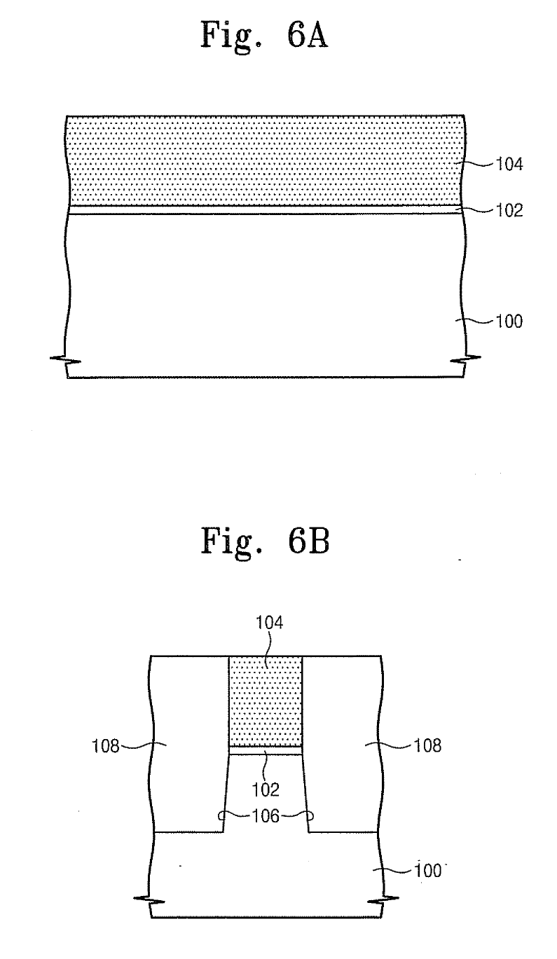

FIGS. 6A-10A and 6B-10B are cross-sectional diagrams taken along lines III-III′ and IV-IV′ of FIG. 2, respectively, that illustrate methods of forming a non-volatile memory device according to certain embodiments of the present invention.

Referring to FIGS. 6A and 6B, a buffer pattern 102 and a hard mask pattern 104 are sequentially stacked on a predetermined region of a substrate 100. The buffer pattern 102 may comprise, for example, a silicon oxide layer. The hard mask pattern 104 may comprise, for example, a material having etching selectivity with respect to the substrate 100, e.g., a silicon nitride layer or a silicon oxide-nitride layer.

The substrate 100 is etched by using the hard mask pattern 104 as an etching mask, thereby forming trenches 106 that define an active region. A device-isolation insulating layer may then be formed on the substrate 100 having the trenches 106. This device-isolation insulating layer may then be planarized to expose the hard mask pattern 104 to thereby form device isolation layers 108. The device isolation layers 108 may comprise silicon oxide.

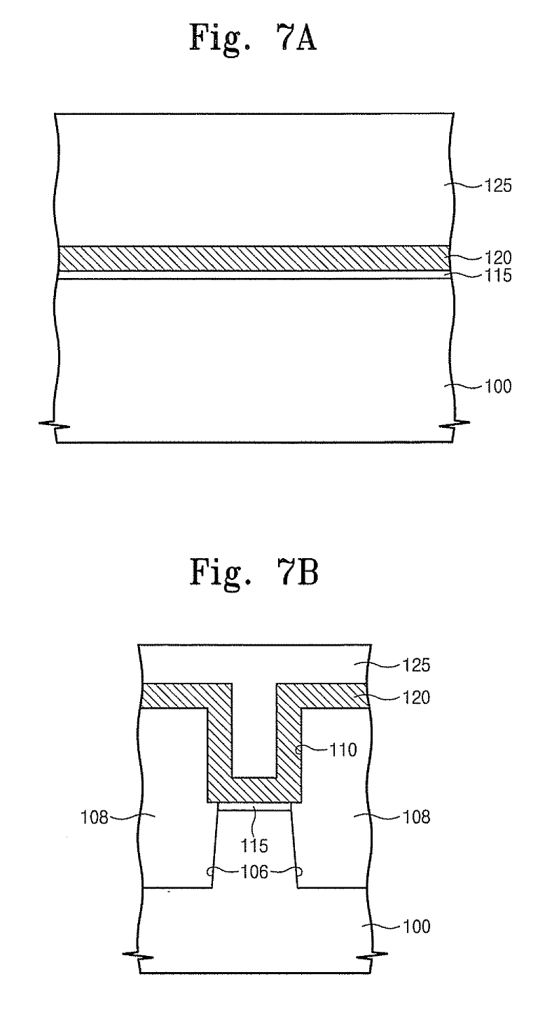

As shown in FIGS. 7A and 71B, the exposed hard mask pattern 104 may be removed to expose the buffer pattern 102, and the buffer pattern 102 may then be removed to expose the active region. Removal of the hard mask pattern 104 and the buffer pattern 102 forms an open area 110 that is defined by portions of the device isolation layers 108 that protrude from the substrate 100. The hard mask pattern 104 may be removed, for example, via isotropic etching or anisotropic etching. The buffer pattern 102 may be removed, for example, by wet etching, which may facilitate reducing and/or preventing plasma damage to the exposed active region. When the buffer pattern 102 is removed by the wet etching, protruding portions of the device isolation layers 108 may be isotropically etched, and thus the width of the open area 110 may be greater than the width of the active region (see FIG. 7B).

A tunnel insulating layer 115 is formed on the exposed active region. The tunnel insulating layer 115 may comprise, for example, a silicon oxide layer, such as a thermal oxide layer. A gate layer 120 is conformally formed on the substrate 100 and the tunnel insulating layer 115. The gate layer 120 may comprise, for example, a doped polysilicon layer. A capping layer 125 is formed on the gate layer 120 in the remaining portion of the open area 110 (i.e., in the above-described void). The capping layer 125 may be formed of an insulating material having etching selectivity with respect to the device isolation layers 108. For example, the capping layer 125 may be formed of a silicon nitride layer or a silicon oxide nitride layer.

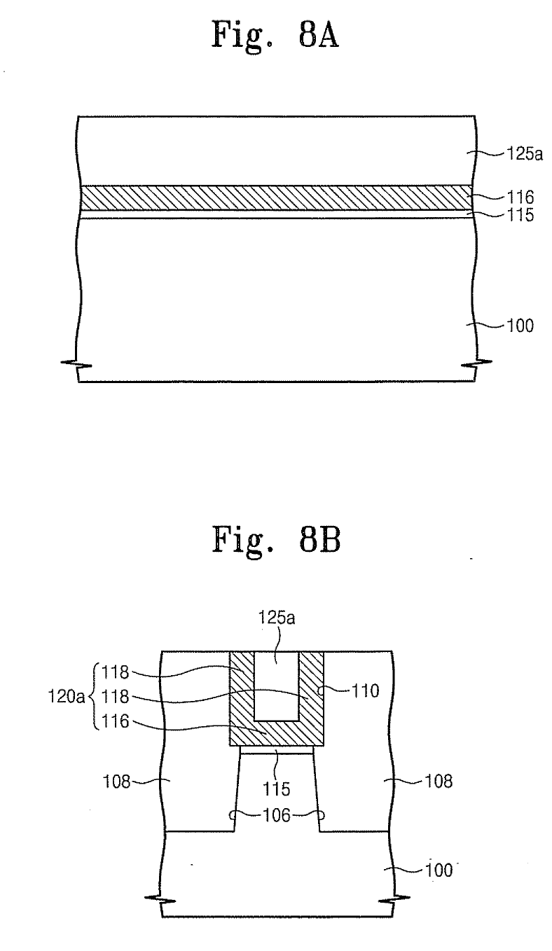

As shown in FIGS. 8A and 8B, the capping layer 125 and the gate layer 120 may be planarized to expose the device isolation layers 108. As a result, a pre-floating gate 120a is formed within the open area 110. The pre-floating gate 20a includes a flat lower portion 116 that is on the tunnel insulating layer 115, the active region, and possibly the device isolation layers 108, and a pair of walls 118 that extend upward from opposite edges of the flat lower portion 116. The walls 118 of the pre-floating gate 120a extend upwardly along side walls of the open area 110 (i.e., side walls of the protruding portions of the device isolation layers 108). The planarized capping layer 125a is deposited in, and may fill, the void defined by the flat lower portion 116 and the walls 118 of the pre-floating gate 120a.

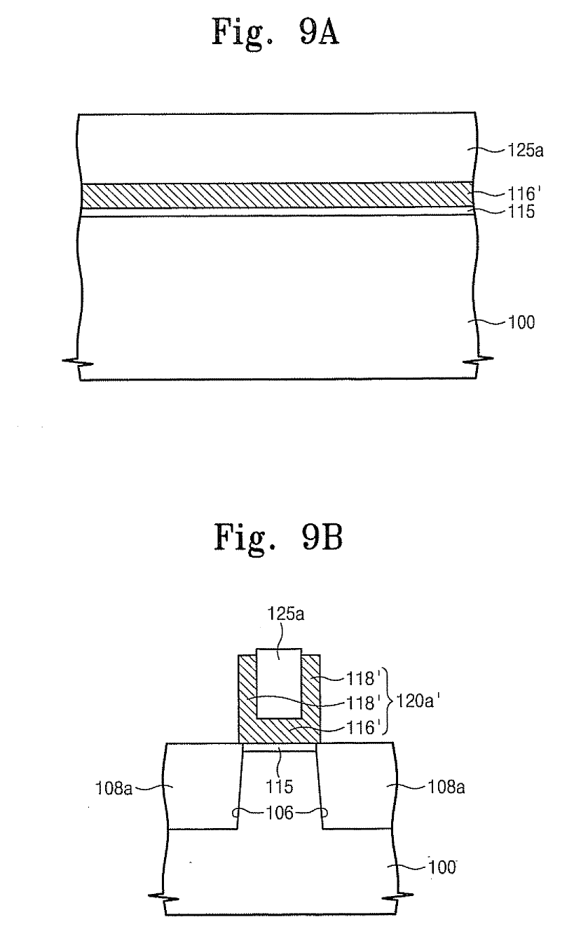

As shown in FIGS. 9A and 9B, the device isolation layers 108 are recessed to expose outer side surfaces of the walls 118 of the pre-floating gate 120a. A top surface of the recessed device isolation layer 108a may, for example, be at or about the same level as a bottom surface of the flat lower portion 116 of the pre-floating gate 120a. In other embodiments, the top surface of the recessed device isolation layer 108a may be lower than the bottom surface of the flat lower portion 116. The planarized capping layer 125a survives the process used to recess the device isolation layers 108 because the planarized capping layer 125a has etching selectivity with respect to the device isolation layer 108.

Isotropic etching is performed on the pre-floating gate 120a. At the time of the isotropic etching, outer surfaces of the walls 118 of the pre-floating gate 120a are exposed and the inner surfaces of the walls 118 and a top surface of the flat lower portion 116 are covered by the planarized capping layer 125a. The bottom surface of the flat lower portion 116 also is not exposed because it is in contact with the tunnel insulating layer 115. The isotropic etching therefore etches the outer surfaces of the walls 118, while the top and bottom surfaces of the flat lower portion 116 are not etched. Consequently, the isotropically-etched flat lower portion 116′ has a thickness that is greater than a width of the isotropically-etched walls 118′ (i.e., the vertical thickness of flat lower portion 116′ exceeds the lateral width of the walls 118′ in FIG. 9B).

The width of the isotropically-etched wall 118′ may be greater than a width of the void defined by the isotropically-etched flat lower portion 116′ and walls 118′. Thus, the top surface of the isotropically-etched wall 118′ may be greater than a planar area of the void.

The planarized capping layer 125a may have etching selectivity with respect to the pre-floating gate 120. Accordingly, the top surface of the planarized capping layer 125a may be higher than the top surface of the walls 118′ of the isotropically-etched floating gate 120a′.

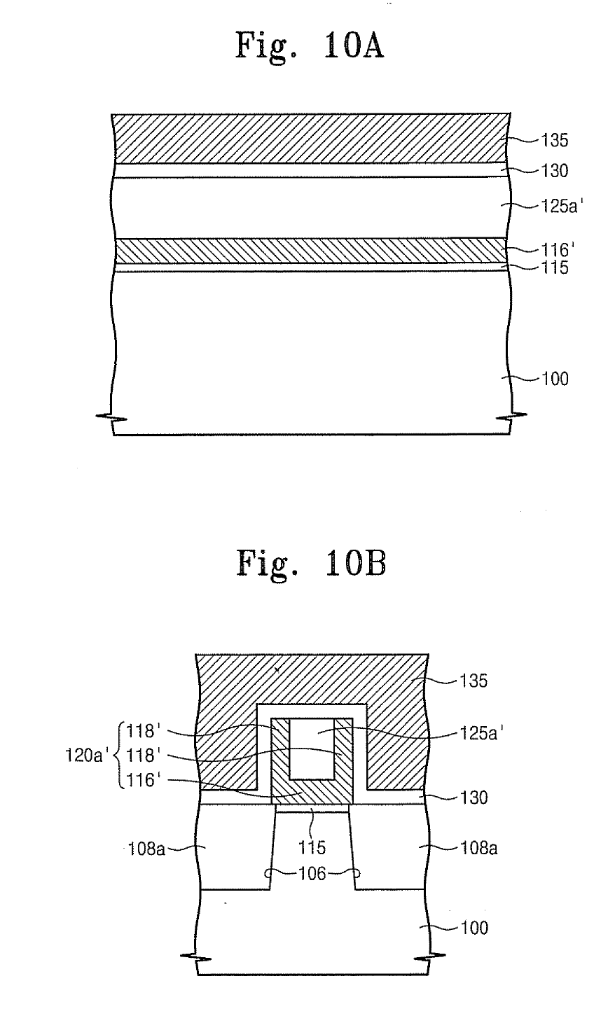

Referring to FIGS. 10A and 10B, the top surface of the planarized capping layer 125a is recessed to be at about the same level as the top surface of the isotropically-etched walls 118′. The recessed capping layer 125a′ fills the void defined by the isotropically-etched walls 118′ and the isotropically-etched flat lower portion 116′. The process of recessing the planarized capping layer 125a may be omitted.

Next, a blocking insulating layer 130 and a control gate conductive layer 135 are sequentially formed on the substrate 100. The blocking insulating layer 130 may comprise, for example, an ONO layer. In other embodiments, the blocking insulating layer 130 may comprise an insulating layer having a dielectric constant higher than that of the tunnel insulating layer 115. For example, the blocking insulating layer 130 may include an insulating metal oxide layer such as a hafnium oxide layer, an aluminum oxide layer, or the like.

The control gate conductive layer 135 may comprise, for example, a single or multi-layer structure of one or more materials selected from the group consisting of a doped polysilicon layer, a metal layer (e.g., a tungsten layer, a molybdenum layer, etc.), a conductive metal nitride layer (e.g., a titanium nitride layer, a tantalum nitride layer, etc.), and a metal silicide layer (e.g., a tungsten silicide layer, a cobalt silicide layer, a titanium silicide layer, a nickel silicide layer, etc.).

The control gate conductive layer 135, the blocking insulating layer 130, the capping layer 125a′, and the pre-floating gate 120′ are patterned to form a floating gate 120b, a capping pattern 125b, a blocking insulating pattern 130 and a control gate electrode 135, which are illustrated in FIGS. 3A and 3B. During etching process(es) that may be part of the patterning process, the void defined by the pre-floating gate 120a′ is filled with the capping layer 125′. The capping layer 125a′ may reduce and/or minimize etching damage to an active region at both sides of the floating gate 120b, which may result from over-etching. In particular, while the blocking insulating layer 130 formed high on the side surface of the walls 118′ is etched, the capping layer 125a′ may protect the flat lower portion 116′ of the floating gate 120b to reduce and/or minimize etching damage to the active region.

The flat lower portion 116a and walls 118a of the floating gate 120b are formed from the flat lower portion 116′ and the walls 118′ of the pre-floating gate 120a′, respectively. Then, impurity ions are doped into the substrate 100 using the control gate electrodes 135a as a mask to form the impurity-doped regions 140 illustrated in FIG. 3A. In such a manner, the non-volatile memory device illustrated in FIGS. 3A and 3B may be implemented.

The non-volatile memory device illustrated in FIGS. 4A and 4B may be formed by a method that is very similar to the method described above. Differences between the method used to form the device illustrated in FIGS. 4A and 4B and the method described above will now be described.

The method of forming the device illustrated in FIGS. 4A and 4B includes the process of recessing the planarized capping layer 125a that is described above with reference to FIGS. 10A and 10B. In the embodiment of FIGS. 4A and 4B, the top surface of the recessed capping layer is lower than a top surface of the isotropically-etched walls 118′. The blocking insulating layer 130 is formed on the top surface of the recessed capping layer to fill the void defined by the isotropically-etched flat lower portion 116′ and walls 118′. Once the blocking insulating layer 130 is formed, the remaining fabrication processes may be identical to the processes described above with reference to FIGS. 10A and 10B to fabricate the non-volatile memory device illustrated in FIGS. 4A and 4B. The void defined by the isotropically-etched walls 118′ and flat lower portion 116 is at least partially filled with an insulating material, so that etching damage to the active region at both sides of the floating gate 120b may be reduced and/or minimized during the etching process employed in forming the gates 135a and 120b.

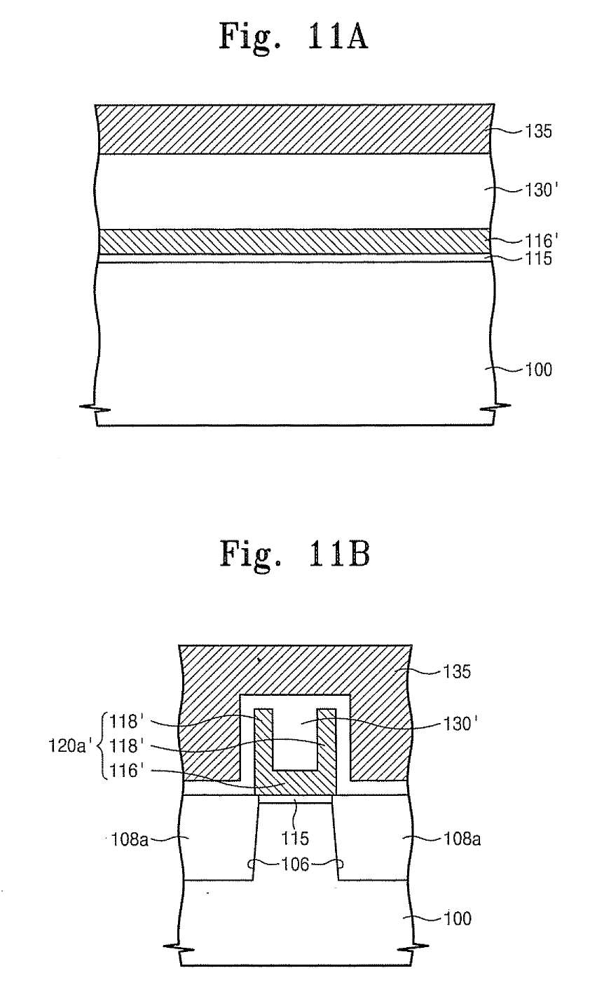

Next, a method of forming a non-volatile memory device illustrated in FIGS. 5A and 5B will be described with reference to FIGS. 11A and 11B, which are cross-sectional diagrams taken along lines III-III′ and IV-IV′ of FIG. 2, respectively.

The method of forming the pre-floating gate 120a and the planarized capping layer 125a may be performed in the same manner as illustrated in FIGS. 6A to 8A and FIGS. 6B to 8B. Then, the device isolation layers 108 are recessed to expose outer sides of the pre-floating gate 120a. As described above, the recessed device isolation layer 108a may be at about the same level as, or lower than, the lower surface of the flat lower portion 116 of the pre-floating gate 120a. The recessed device isolation layer 108a may cover side surfaces of the tunnel insulation layer 115. Isotropic etching is then performed on the pre-floating gate 120a, so that the thickness of the isotropically-etched flat lower portion 116′ is greater than the width of the isotropically-etched walls 118′. The planarized capping layer 125a is then removed to expose inner surfaces of the isotropically-etched pre-floating gate 120a′ (i.e., a top surface of the isotropically-etched flat lower portion 116′ and inner surfaces of the walls 118′).

The planarized capping layer 125a may be formed of an insulating material having etching selectivity with respect to the device isolation layer 108. Thus, after the device isolation layers 108 are recessed, the isotropic etching may be performed on the pre-floating gate 120a, and then the planarized capping layer 125a may be removed.

In other embodiments, the planarized capping layer 125a may be formed of an insulating layer that has etching selectivity that is the same as or similar to the etching selectivity of the device isolation layer 108. In such embodiments, the recessing of the device isolation layers 108 and the removal of the planarized capping layer 125a may be performed simultaneously, and then the isotropic etching may be performed on the pre-floating gate 120a. Here, the inner and outer sides of the walls 118 of the pre-floating gate 120 are all exposed, as is the top surface of the flat lower portion 116 of the pre-floating gate 120a. Thus, the thickness of the isotropically etched flat lower portion 116′ can be still greater than the width of the isotropically etched walls 118′. The width of the isotropically-etched walls 118′ may be greater than the width of the void defined by the isotropically-etched flat lower portion 116′ and the walls 118′.

Next, the blocking insulating layer 130′ may be formed on the substrate 100. The blocking insulating layer 130′ may fill the void defined by the isotropically-etched pair of walls 118′ and the flat lower portion 116′ of the pre-floating gate 120a. The blocking insulating layer 130′ may have a thickness as great as half or more of the width of the void (i.e., the distance between the isotropically-etched pair of walls 118′). Thus, the blocking insulating layer 130′ may fill the void while conformally covering the outer surfaces of the isotropically etched walls 118′. The blocking insulating layer 130′ may comprise, for example, an ONO layer, or may include an insulating layer having a high dielectric constant as compared to that of the tunnel insulating layer 115 (e.g., insulating metal oxide layers such as a hafnium oxide layer, aluminum oxide layer or the like).

A control gate conductive layer 135 is formed on the blocking insulating layer 130′. The control gate conductive layer 135, the blocking insulating layer 130′, and the pre-floating gate 120a′ are sequentially patterned to form the floating gate 120b, the blocking insulating pattern 130b, and the control gate electrode 135 illustrated in FIGS. 5A and 5B. Doping of impurity ions is performed using the control gate electrode 135a as a mask to form impurity doped regions 140a illustrated in FIG. 5A to complete fabrication of the device illustrated in FIGS. 5A and 5B.

In the above-described method, the portion of the blocking insulating layer 130′ that is deposited in the void in the pre-floating gate 120a can reduce and/or minimize etching damage to the active region at both sides of the pre-floating gate 120b which may otherwise occur during etching processes used in forming the gates 135a and 120b. Also, the thickness of the flat lower portion 116′ of the pre-floating gate 120a′ may be sufficient to further reduce and/or minimize etching damage to the active region. Also, the other effects described with reference to the embodiments of FIGS. 3A and 3B may be obtained.

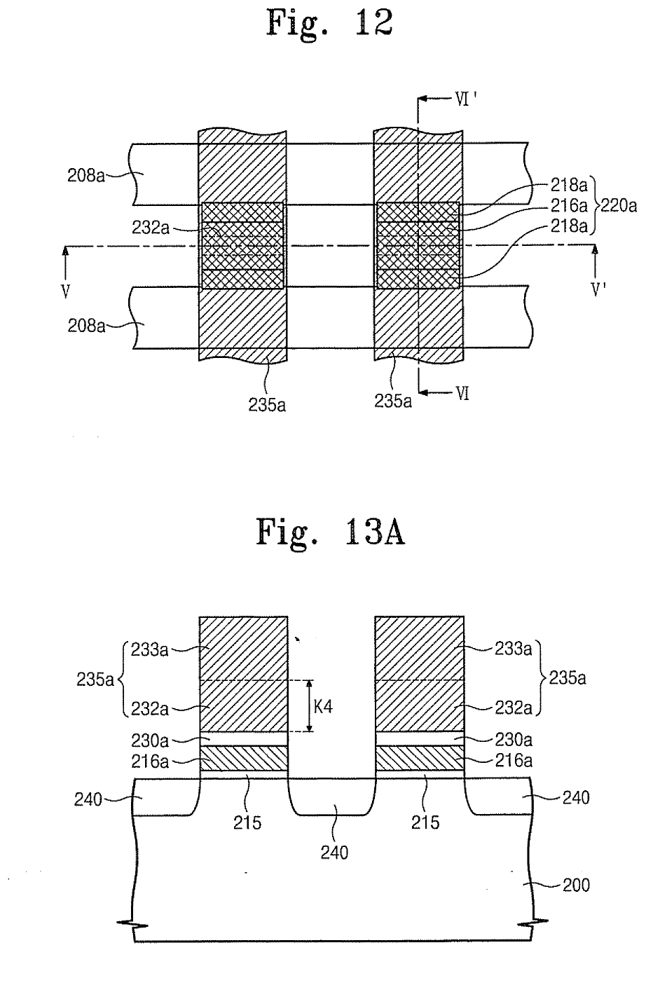

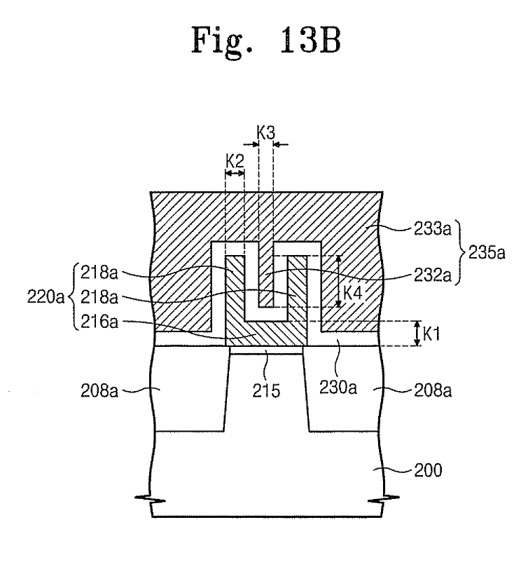

FIG. 12 is a plan view illustrating a non-volatile memory device according to further embodiments of the present invention. FIGS. 13A and 13B are cross-sectional diagrams taken along lines V-V and VI-VI′ of FIG. 12, respectively.

Referring to FIGS. 12, 13A and 13B, device isolation layers 208a are disposed in a substrate 200 to define an active region. The device isolation layers 208a may fill trenches 206 that are formed in the substrate 200. A floating gate 220a is disposed on the active region, and a tunnel insulating layer 215 is interposed between the floating gate 220a and the active region. Impurity-doped regions 240 are disposed at both sides of the floating gate 220a in the active region.

The floating gate 220a includes a flat lower portion 216a and a pair of facing walls 218a that extend upward from edges of the flat lower portion 216. The walls 218a extend upward from respective edges of the flat lower portion 216a that are adjacent to the device isolation layer 208a. A top surface of the device isolation layer 208a may be at almost the same level to, or lower than, a bottom surface of the flat lower portion 216a. The device isolation layer 208 may cover a side surface of the tunnel insulation layer 215. A void is defined by the flat lower portion 216a and the pair of walls 218a. This void is open at the top and at the sides that are adjacent to the impurity-doped regions 240. As shown in FIG. 13B, a thickness (K1) of the flat lower portion 216a may be greater than a width (K2) of the walls 218a. As also shown in FIG. 13B, the width (K2) of the walls 218a is the distance between an outer surface of the wall 218a adjacent to the device isolation layer 208a and its opposite inner surface.

A control gate electrode 235a is disposed on the floating gate 220a. The control gate electrode 235a is formed across the active region (see FIG. 12). A conformal blocking insulating pattern 230a is disposed between the floating gate 220a and the control gate electrode 235a. As shown in FIG. 13B, the control gate electrode 235a includes a gap-fill portion 232a and a peripheral portion 233a. The peripheral portion 233a covers outer sides of the floating gate 220a (i.e., the outer surfaces of the walls 218a) and top portions thereof with the blocking insulating pattern 230a interposed therebetween. The gap-fill portion 232a extends into the void with the blocking insulating pattern 230a interposed therebetween. The blocking insulating layer 230a may be conformally formed within the void and may come in contact with the flat lower portion 216a and the walls 218a of the pre-floating gate 220a. The width (K2) of the walls 218a may be greater than the width (K3) of the gap-fill portion 232a.

If the floating gate 220a is formed of doped polysilicon, the width (K2) of the wall 218a may be partially depleted when an operating voltage is applied to the control gate electrode 235a. Thus, it is possible to reduce and/or minimize a decrease in electrostatic capacitance between the control gate electrode 235a and the floating gate 220a due to a depletion layer.

As shown in FIG. 13A, side surfaces of the floating gate 220a, of the blocking insulating pattern 230a, and of the control gate electrode 235a, which are adjacent to the impurity-doped regions 240, are aligned with each other.

The value obtained by subtracting a thickness of the blocking insulating pattern 230a from a depth of the void (the depth of the void is the interval between the top surfaces of the walls 218a and the top surface of the flat lower portion 216a), may be greater than the thickness (K1) of the flat lower portion 216a. The value obtained by subtracting the thickness of the blocking insulating pattern 230 from the depth of the void may correspond to the height (K4) of the gap-fill portion 232. Accordingly, the height (K4) of the gap-fill portion 232a is greater than the thickness (K1) of the flat lower portion 216a.

Non-volatile memory devices having the aforementioned structure have floating gates 220a that include the flat lower portion 216a and the pair of walls 218a. Thus, the side area of the floating gate 220b adjacent to the impurity-doped regions 240 is reduced by the side area of the void. As a result, the degree of overlap between adjacent floating gates 220a decreases, thereby reducing a parasitic electrostatic capacitance.

In addition, the control gate electrode 235a covers not only the outer and top surfaces of the walls 218a but also the inner surfaces thereof. Accordingly, an overlap area between the control gate electrode 235a and the floating gate 220a is increased, and thus a coupling ratio of the non-volatile memory cell increases.

Furthermore, the width (K2) of the walls 218a is greater than the width (K3) of the gap-fill portion 232a. Therefore, the walls 218a have a sufficient width to be partially depleted when an operating voltage is applied, and the width (K3) of the gap-fill portion 232a is small, so that a highly-integrated non-volatile memory device may be implemented. That is, because the walls 218a are sufficient wide to be partially depleted and the width (K3) of the gap-fill portion 232a is relatively small, the planar area of the non-volatile memory cell may likewise be small.

Furthermore, the thickness (K1) of the flat lower portion 216a is greater than the width (K2) of the walls 218a. Thus, the etching damage to the active region at both sides of the floating gate 220a during the process steps for forming the control gate electrode 235a, the blocking insulating pattern 230a, and the floating gate 220a may be reduced and/or minimized.

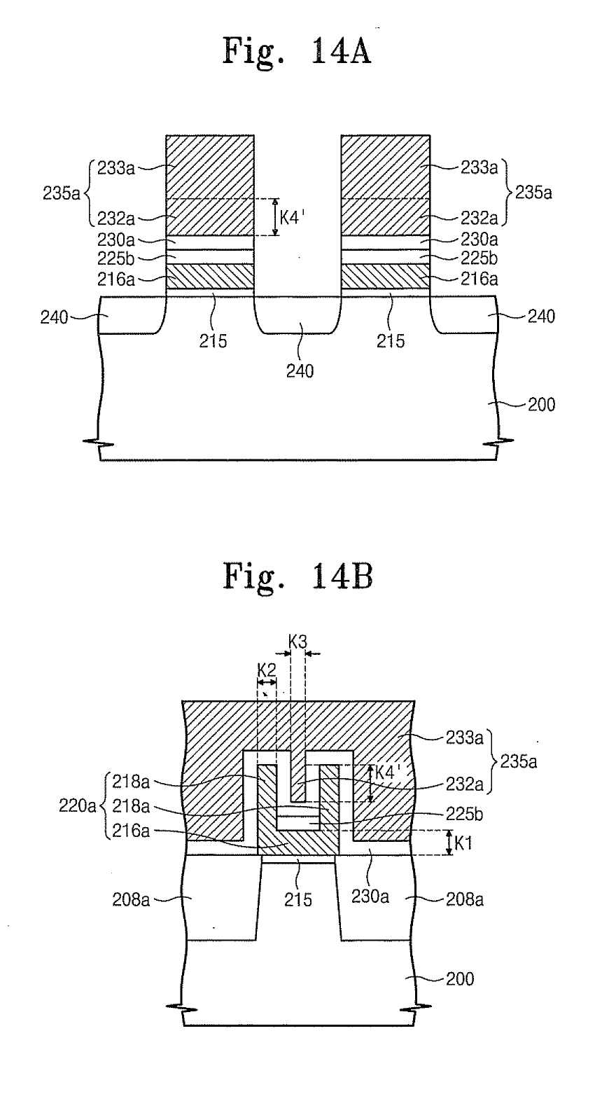

Pursuant to further embodiments of the present invention, different materials may be disposed within the void defined by the flat lower portion 216a and the pair of walls 218a. FIGS. 14A and 14B are cross-sectional diagrams taken along lines V-V′ and VI-VI′ of FIG. 12, respectively, illustrating a non-volatile memory device according to further embodiments of the present invention that uses such alternate materials.

Referring to FIGS. 14A and 14B, a capping pattern 225b is disposed between a blocking insulating pattern 230a and a flat lower portion 216a within the void defined by the flat lower portion 216a and a pair of walls 218a. The capping pattern 225b is formed of an insulating material such as, for example, an insulating material having etching selectivity with respect to the device isolation layer 225b. A gap-fill pattern 232a of a control gate electrode 235a is disposed on the capping pattern 225b. The value obtained by subtracting the thickness of the blocking insulating pattern 230a from the depth of the void is greater than a thickness (K1) of the flat lower portion 216a. That is, a value obtained by adding a height (K4′) of the gap-fill portion 232a to a thickness of the capping pattern 225b may be greater than the thickness (K1) of the flat lower portion 216a.

The width (K2) of the walls 218a may be greater than a width (K3) of the gap-fill portion 232a. The elements having the same references numerals as those of FIGS. 13A and 13B have the same features as illustrated above with reference to FIGS. 13A and 13B.

The non-volatile memory device having the aforementioned structure may obtain all the effects discussed above with reference to FIGS. 13A and 13B. Furthermore, the capping pattern 225b may further reduce and/or minimize the etching damage to the active region at both sides of the floating gate 220a, which may be caused by the etching process used to form the control gate electrode 235a, the blocking insulating pattern 230a, and/or the floating gate 220a.

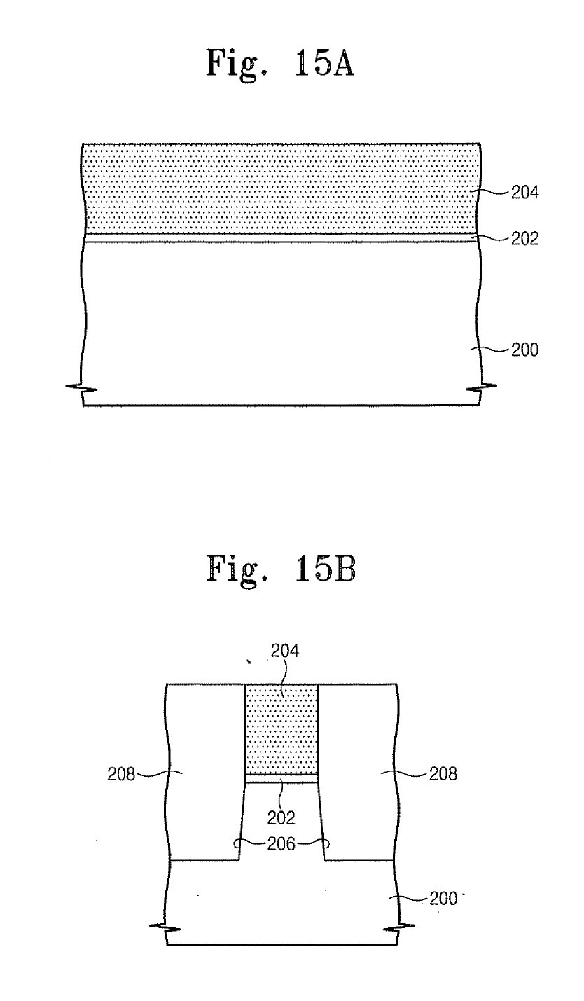

FIGS. 15A to 17A and FIGS. 15B to 17B are cross-sectional diagrams taken along lines V-V′ and VI-VI′, respectively, of FIG. 12 that illustrate methods of forming the non-volatile memory device of FIGS. 13A and 13B.

Referring to FIGS. 15A and 15B, a buffer pattern 202 and a hard mask pattern 204, which are sequentially stacked, are formed on a predetermined area of a substrate 200, and the substrate 200 is etched using the hard mask pattern 204 as an etching mask to form trenches 206 that define an active region. The buffer pattern 202 may comprise, for example, a silicon oxide layer, and the hard mask pattern 204 may comprise a material having etching selectivity with respect to the substrate 200, for example, a silicon nitride layer or a silicon oxide nitride layer.

A device isolation insulating layer is formed in the trenches 206, and is planarized to expose the hard mask pattern 204 to form device isolation layers 208. The device isolation layer 208 may comprise, for example, a silicon oxide layer.

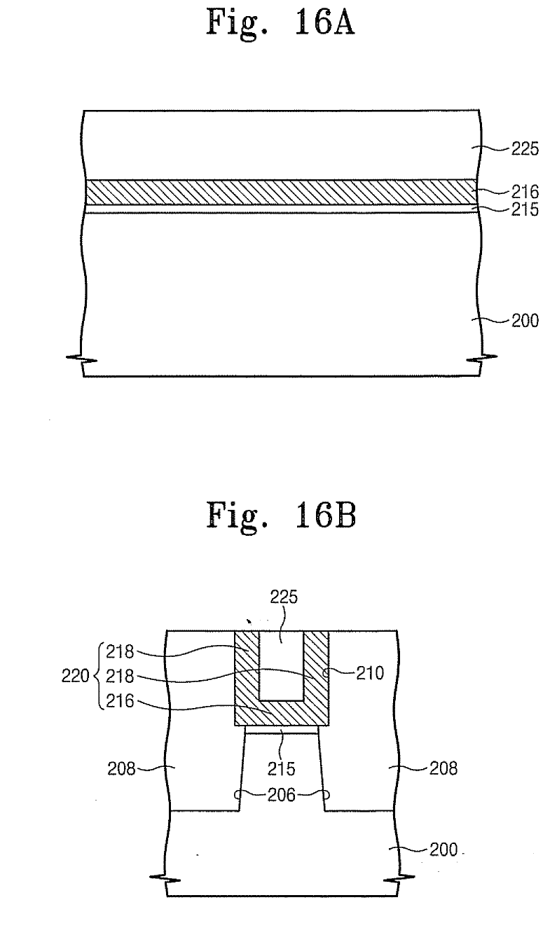

Referring to FIGS. 16A and 16B, the exposed hard mask pattern 204 and the buffer pattern 202 are removed to form an open area 210 that exposes the active region. The open area 210 is defined by portions of the device isolation layers 208 that protrude upward from the substrate 200. The buffer pattern 202 may be removed by wet etching to reduce and/or prevent plasma damage to the exposed active region. The open area 210 may have a width greater than the width of the active region, as the protruding portions of the device isolation layers 208 are etched when the buffer pattern 202 is removed by the wet etching

As shown in FIGS. 16A and 16B, a tunnel insulating layer 215 is formed on the exposed active region, and a gate layer is conformally formed on the substrate 200. A capping layer that may fill the open area 210 is formed on the gate layer. The tunnel insulating layer 215 may comprises a silicon oxide layer, particularly, a thermal oxide layer. The gate layer may comprise a doped polysilicon layer. The capping layer may comprise an insulating material having etching selectivity with respect to the device isolation layer 208 such as, for example, a silicon nitride layer or a silicon oxide nitride layer. In other embodiments, the capping layer may be formed of an insulating material having an etching ratio that is the same as or similar to that of the device isolation layer 208 such as, for example, a silicon oxide layer.

The capping layer and the gate layer are planarized to expose the device isolation layers 208 to form a sequentially-stacked pre-floating gate 220 and planarized capping layer 225 within the open area 210. The pre-floating gate 220 includes a flat lower portion 216 that is disposed on the tunnel insulating layer 215 and a pair of facing walls 218 that extend upward from opposite edges of the flat lower portion 216. The walls 218 extend upward along side walls of the open area 210 (i.e., side walls of protruding portions of the device isolation layer 208). Each wall 218 has an outer surface adjacent to the device isolation layer 208 and an inner surface opposite to the outer surface.

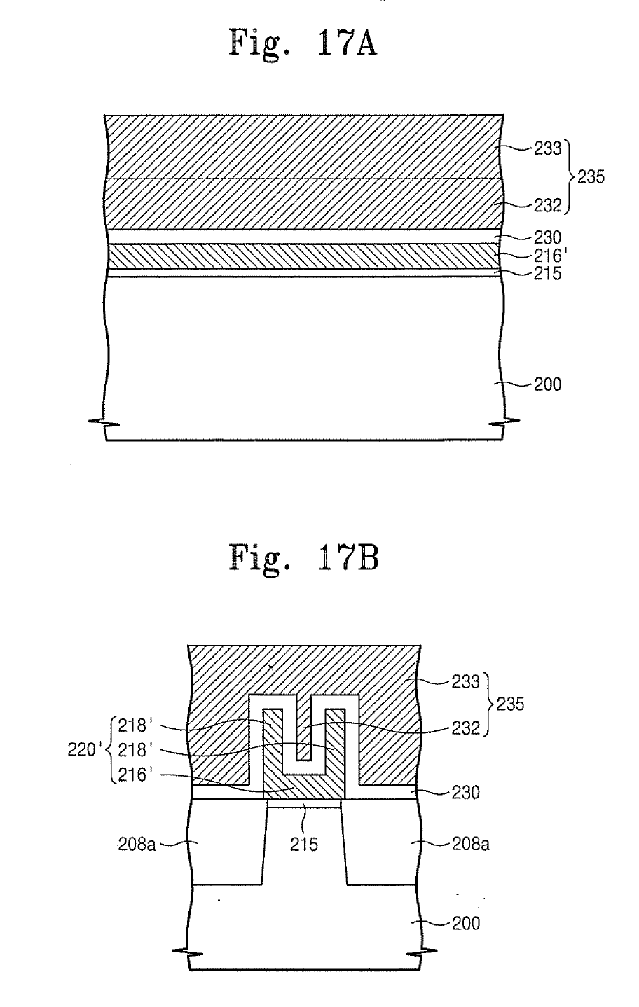

As shown in FIGS. 17A and 17B, the device isolation layer 208 is recessed to expose outer surfaces of the pre-floating gate 220. A top surface of the recessed device isolation layer 208 may be at about the same level as, or lower than, a bottom surface of the flat lower portion 216. Isotropic etching is performed on the pre-floating gate 220. Accordingly, a thickness of flat lower portion 216 of the isotropically-etched pre-floating gate 220′ may become greater than a width of the isotropically etched walls 218′. The planarized capping layer 225 is removed.

When the planarized capping layer 225 is formed of a material having etching selectivity similar to, or the same as, that of the device isolation layer 208, the recessing of the device isolation layer 208 and the removing of the planarized capping layer 225 may be performed simultaneously. In this case, the isotropic etching process may be performed after the recessing of the device isolation layer 208 and the removing of the planarized capping layer 225.

When the planarized capping layer 225 is formed of a material having etching selectivity with respect to the device isolation layer 208, the recessing of the device isolation layer 208 is performed, and then the isotropic etching is performed on the pre-floating gate 220. After the isotropic etching, the planarized capping layer 225 is removed.

Next, a blocking insulating layer 230 is conformally formed on the substrate 200, and a control gate conductive layer 235 that fills the void defined by the isotropically-etched flat lower portion 216′ and walls 218′ is formed on the blocking insulating layer 230. The control gate conductive layer 235 includes a gap-fill portion 232 that fills the remainder of the void, and a peripheral portion 233 that surrounds the pre-floating gate 220′. The width of the walls 218′ of the pre-floating gate 220′ may be greater than the width of the gap-fill portion 232 of the control gate conductive layer 235.

The value obtained by subtracting the thickness of the blocking insulating layer 230 from the depth of the void (the depth of the void is the interval between the top surfaces of the walls 218′ and the top surface of the flat lower portion 216′) may be greater than the thickness of the flat lower portion 216′.

The blocking insulating layer 230 may comprise, for example, an ONO layer or an insulating layer having a higher dielectric constant than the tunnel insulating layer 215 (e.g., metal oxide layers such as a hafnium oxide layer or an aluminum oxide layer). The control gate conductive layer 235 may comprise, for example, a doped polysilicon layer, a metal layer (e.g., a tungsten layer, a molybdenum layer, etc.), a conductive metal nitride layer (e.g., a titanium nitride layer, a tantalum nitride layer, etc.), a metal silicide layer (e.g., a tungsten silicide layer, a cobalt silicide layer, a titanium silicide layer, a nickel silicide layer, etc.), or combinations thereof.

The control gate conductive layer 235, the blocking insulating layer 230, and the pre-floating gate 220′ are sequentially patterned to form the floating gate 220a, the blocking insulating pattern 230a, and the control gate electrode 235a illustrated in FIGS. 13A and 13B. The thickness of the flat lower portion 216′ of the pre-floating gate 220′ may be sufficient to reduce and/or minimize etching damage to the active region at both sides of the floating gate 220a during any etching processes of the patterning process.

Impurity ions are doped into the substrate 200 using the control gate electrode 235a as a mask to form the impurity-doped regions 240 illustrated in FIG. 13A. Thus, a non-volatile memory device illustrated in FIGS. 13A and 13B can be implemented.

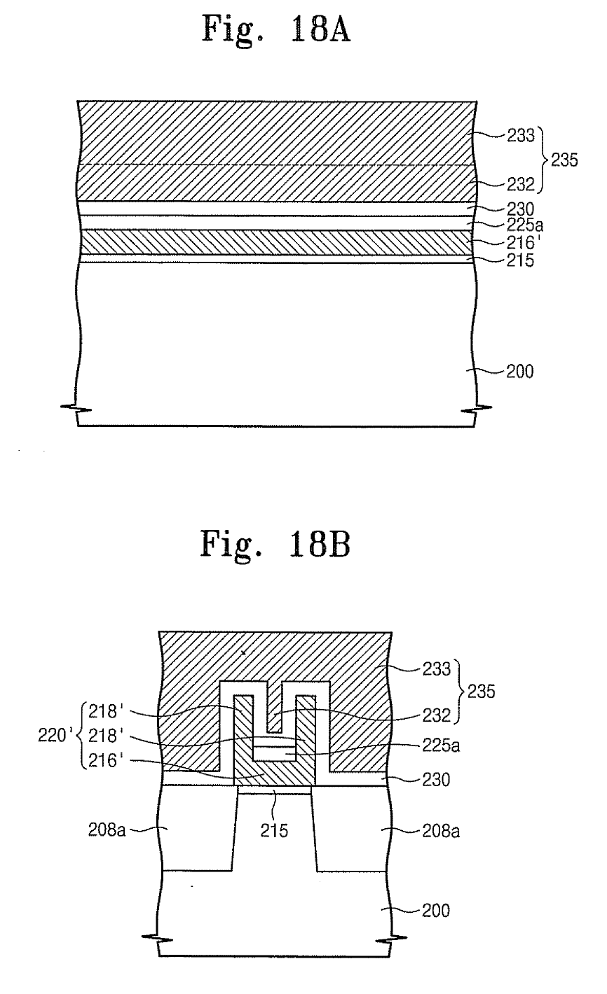

A method of forming a non-volatile memory device illustrated in FIGS. 14A and 14B will now be described with reference FIGS. 15A, 15B, 16A and 16B, and with respect to FIGS. 18A and 18B, which are cross-sectional diagrams taken along lines V-V′ and VI-VI′, respectively, of FIG. 12.

The method of forming the pre-floating gate 220 and the planarized capping layer 225 may be performed in the same manner as discussed in the above-described embodiments with reference to FIGS. 15A, 15B, 16A and 16B. Then, to form the device of FIGS. 18A and 18B, the planarized capping layer 225 may be formed of an insulating layer having etching selectivity with respect to the device isolation layer 208. The device isolation layers 208 are recessed to expose outer sides of the walls 218 of the pre-floating gate 220. Isotropic etching is performed on the pre-floating gate 220 such that a thickness of the isotropically-etched flat lower portion 216′ is greater than a thickness of the isotropically-etched walls 218′.

The planarized capping layer 225 is recessed such that a top surface of the recessed capping layer 225a is lower than a top surface of the isotropically-etched walls 218′. Then, a blocking insulating layer 230 is conformally formed on the substrate 200 having the recessed capping layer 225, and a control gate conductive layer 235 is formed on the blocking insulating layer 230, thereby filling the void defined by the isotropically-etched flat lower portion 216′ and walls 218′.

The interval between the top surface of the recessed capping layer 225a and the top surface of the isotropically-etched walls 218′ may be greater than the thickness of the blocking insulating layer 230. Thus, the control gate conductive layer 235 has a gap-fill portion 232 filling the void.

The control gate conductive layer 235, the blocking insulating layer 230, the recessed capping layer 225a, and the pre-floating gate 220′ are sequentially patterned to form the floating gate 220a, the capping pattern 225b, the blocking insulating pattern 230a, and the control gate electrode 235a illustrated in FIGS. 14A and 14B. The recessed capping layer 225 may help reduce and/or minimize etching damage to the active region at both sides of the floating gate 220 during the etching processes of the patterning process. The flat lower portion 216′ of the pre-floating gate 220′ may also protect the active region from etching damage.

Impurity ions are doped by using the control gate electrode 235a as a mask to form the impurity-doped regions 240 of FIG. 14A. Thus, the non-volatile memory device of FIGS. 14A and 14B can be implemented.

As described above, according to embodiments of the present invention, a floating gate includes a flat lower portion and a pair of walls that extend upward from both edges of the flat lower portion. Accordingly, the area of each side surface of the floating gate that is adjacent to the impurity-doped regions is reduced by the side area of the void defined by the flat lower portion and the walls. As a result, the overlap area between adjacent floating gates decreases, which may help reduce and/or minimize the parasitic electrostatic capacitance between adjacent floating gates.

The void defined by the flat lower portion and the walls of the pre-floating gate may be filled with an insulating material. Thus, etching damage to the active region at both sides of the floating gate during etching processes used to form the control gate electrode and/or the floating gate may also be reduced and/or minimized.

The control gate electrode may include a gap-fill portion that extends into the void defined by the floating gate. A width of the wall of the floating gate may be greater than a width of the gap-fill portion of the control gate electrode. Thus, the wall of the floating gate may have a sufficient width to be partially depleted, and a planar area of the non-volatile memory cell may decrease. Accordingly, a decrease in an electrostatic capacitance between the control gate electrode and the floating gate due to a depletion layer can be reduced and/or minimized, and a highly-integrated non-volatile memory device can be implemented.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. A non-volatile memory device comprising:
an active region in a semiconductor substrate;
a floating gate on the active region, the floating gate comprising a lower portion and a pair of facing walls extending upward from opposite edges of the lower portion that define a void above the lower portion;
a tunnel insulating layer between the active region and the lower portion of the floating gate;
a control gate electrode on the floating gate and covering outer surfaces of the pair of facing walls;
one or more insulating materials interposed between the control gate electrode and the floating gate, the one or more insulating layers filling the void; and
first and second impurity-doped regions in the active region at opposite sides of the control gate electrode.

2. The non-volatile memory device of claim 1, wherein the one or more insulating materials comprise a capping pattern that at least partially fills the void and a blocking insulation pattern that is interposed between the control gate electrode and the floating gate.

3. The non-volatile memory device of claim 2, wherein a top surface of the capping pattern is at least at about the same height above the substrate as a top surface of at least one of the walls.

4. The non-volatile memory device of claim 2, wherein a top surface of the capping pattern is lower than a top surface of at least one of the walls so that the capping pattern does not completely fill the void, and wherein the blocking insulation pattern is deposited in at least a portion of the remainder of the void.

5. The non-volatile memory device of claim 2, wherein a side surface of the capping pattern that is adjacent the first impurity-doped region is aligned with a side surface of the floating gate that is adjacent the first impurity-doped region.

6. The non-volatile memory device of claim 1, wherein the one or more insulating materials consists of a blocking insulating pattern that fills the void and that is interposed between the control gate electrode and the floating gate.

7. The non-volatile memory device of claim 1, wherein a thickness of the lower portion is greater than a width of at least one of the walls.

8. The non-volatile memory device of claim 1, wherein a width of at least one of the walls is greater than a width of the void.

9. The non-volatile memory device of claim 1, wherein the walls comprise doped polysilicon, and wherein the walls are configured so as to be partially depleted when an operating voltage is applied to the control gate electrode.

10. The non-volatile memory device of claim 1, wherein a side surface of the floating gate that is adjacent the first impurity-doped region is aligned with side surface of the control gate electrode that is adjacent the first impurity-doped region.

11. The non-volatile memory device of claim 1, wherein each of the facing walls of the floating gate are normal to the lower portion of the floating gate.

12. The non-volatile memory device of claim 1, wherein a height of a lower surface of the control gate above the substrate is lower than a height of a top surface of the lower portion of the floating gate above the substrate.

13. The non-volatile memory device of claim 1, wherein the lower portion of the floating gate is flat and extends parallel to a major axis of the substrate.

14. The non-volatile memory device of claim 1, wherein the active region in the substrate is defined by a device isolation layer, and wherein a lower surface of the lower portion is on the device isolation layer.

15. The non-volatile memory device of claim 6, wherein the thickness of the blocking insulation pattern is at least half the width of the void.

16. A non-volatile memory device comprising:
an active region in a semiconductor substrate;
a floating gate on the active region, the floating gate comprising a lower portion and a pair of facing walls extending upward from opposite edges of the lower portion that define a void above the lower portion;
a tunnel insulating layer between the active region and the lower portion of the floating gate;
one or more insulating materials on the lower portion of the floating gate that partially fill the void;
a control gate electrode on the one or more insulating materials, the control gate electrode covering outer surfaces of the pair of facing walls and including a gap-fill portion that has a width that is less than a width of each of pair of facing walls, the gap-fill portion extending into the void; and
first and second impurity-doped regions in the active region at opposite sides of the control gate electrode.

17. The non-volatile memory device of claim 16, wherein the one or more insulating materials comprise a capping pattern that at least partially fills the void and a blocking insulation pattern that is interposed between the control gate electrode and the capping pattern.

18. The non-volatile memory device of claim 17, wherein a side surface of the capping pattern that is adjacent the first impurity-doped region is aligned with a side surface of the floating gate that is adjacent the first impurity-doped region.

19. The non-volatile memory device of claim 16, wherein a thickness of the lower portion is greater than a width of at least one of the walls.

20. The non-volatile memory device of claim 16, wherein the walls comprise doped polysilicon, and wherein the walls are configured so as to be partially depleted when an operating voltage is applied to the control gate electrode.

21. The non-volatile memory device of claim 16, wherein a value obtained by subtracting a thickness of the blocking insulating pattern from a depth of the void is greater than a thickness of the lower portion.

22. The non-volatile memory device of claim 16, wherein a side surface of the floating gate that is adjacent the first impurity-doped region is aligned with side surface of the control gate electrode that is adjacent the first impurity-doped region.

23. A method of forming a non-volatile memory device, the method comprising:
forming device isolation layers in a substrate to define an active region;
forming a tunnel insulating layer on the active region;
forming a pre-floating gate on the tunnel insulating layer, the pre-floating gate including a flat lower portion covering the active region and a pair of facing walls extending upward from opposite edges of the flat lower portion;
filling a void defined by the flat lower portion and the pair of facing walls with an insulating material;
forming a blocking insulating layer on at least the flat lower portion and at least part of the outer surfaces of the walls of the pre-floating gate;
forming a control gate conductive layer on the blocking insulating layer; and
forming a floating gate, an insulating material pattern, a blocking insulating pattern, and a control gate electrode, which are sequentially stacked, by patterning the control gate conductive layer, the blocking insulating layer, the insulating material, and the pre-floating gate.

24. The method of claim 23, wherein filling the void with the insulating material comprises forming a capping layer filling at least a part of the void.

25. The method of claim 24, wherein a top surface of the capping layer is at least at about the same level as a top surface of at least one of the walls.

26. The method of claim 24, wherein a top surface of the capping layer is lower than a top surface of at least one of the walls, and wherein the blocking insulating layer is formed to fill a remainder of the void above the capping layer so that the insulating material comprises the capping layer and the portion of the blocking insulating layer that fills the remainder of the void.

27. The method of claim 23, wherein the blocking insulating layer is formed to completely fill the void.

28. The method of claim 23, further comprising isotropically etching the pre-floating gate to make a thickness of the flat lower portion greater than a width of the walls.

29. The method of claim 23, wherein the floating gate is formed of doped polysilicon, and the walls of the floating gate have a width that allow the walls to be partially depleted when an operating voltage is applied to the control gate electrode.

30. The method of claim 23, wherein a width of at least one of the walls exceeds a width of the void.

31. A method of forming a non-volatile memory device, the method comprising:
forming device isolation layers in a substrate to define an active region;
forming a tunnel insulating layer on the active region;
forming a pre-floating gate on the tunnel insulating layer, the pre-floating gate including a lower portion covering the active region and a pair of walls extending upward from opposite edges of the lower portion that define a void above the lower portion;
conformally forming a blocking insulating layer on the substrate, the blocking insulating layer partially filling the void;
forming a control gate conductive layer on the blocking insulating layer, the control gate conductive layer covering outer surfaces of the walls, the control gate conductive layer including a gap-fill portion that fills the remainder of the void; and
forming a floating gate, blocking insulating pattern, and a control gate electrode, which are sequentially stacked, by patterning the control gate conductive layer, the blocking insulating layer, and the pre-floating gate,
wherein a width of at least one of the walls of the pre-floating gate is greater than a width of a gap-fill portion of the control gate conductive layer.

32. The method of claim 31, further comprising forming a capping layer on the lower portion to partially fill the void prior to forming the blocking insulating layer, the capping layer being patterned together with the pre-floating gate.

33. The method of claim 31, further comprising isotropically etching the pre-floating gate to make a thickness of the lower portion greater than a width of at least one of the walls.

34. The method of claim 31, wherein the floating gate is formed of doped polysilicon, and the walls of the floating gate have a width that allow the walls to be partially depleted when an operating voltage is applied to the control gate electrode.

35. The method of claim 31, wherein a value obtained by subtracting a thickness of the blocking insulating layer from a depth of the void is greater than a thickness of the lower portion.
